(19) United States
(12) Patent Application Publication
(10) Pub. No.: US 2025/0087989 A1
(43) Pub. Date: Mar. 13, 2025

(54) POWER DISTRIBUTION

(71) Applicant: LSC Control Systems Pty Ltd, Dandenong South, Victoria (AU)

(72) Inventors: Gary Steven PRITCHARD, Dandenong South (AU); Stephen Richie MICKAN, Dandenong South (AU); David BURCHELL, Dandenong South (AU)

(21) Appl. No.: 18/722,425

(22) PCT Filed: Dec. 21, 2021
(86) PCT No.: PCT/AU2021/051527

§ 371 Date: Jun. 20, 2024

(51) Int. Cl. H02H 3/10; G01R 31/327; H05B 47/25; H05B 47/26

(52) U.S. Cl. CPC H02H 3/105; G01R 31/3275; H05B 47/25; H05B 47/26

(57) ABSTRACT

A power distribution system comprises a power inlet. Two or more power outputs each have a respective user-actuatable shut-off and a respective RCD. An ELC monitoring system provides a respective measure of ELC for each of the power outputs. The power distribution system comprises a memory configured to store a respective measured trip point for each respective RCD.

### CROSS-REFERENCE TO RELATED APPLICATIONS

This application is a U.S. National Stage of International Patent Application No. PCT/AU2021/051527 filed Dec. 21, 2021, which is incorporated by reference herein as if reproduced in its entirety.

### FIELD

The disclosure relates to power distribution.

### BACKGROUND

In many contexts, there is a need for a power distribution system to distribute power to various loads. By way of example, a theatre may have dozens of lights to power to suit a particular play, and an entirely different set of lights to power for a different play the next day. Similar requirements exist in connection with film and television, fetes and fairs, sideshows and events more generally.

Historically, power distribution systems have comprised a power inlet, e.g. a lead and plug, to draw power from a power supply, and a set of outputs. In this industry and herein:
a power outlet is a reference to a feature (sometimes referred to as a general power outlet (GPO) or a power socket) with which a complementary plug can be mated; and
a power output is a more general term referring to a feature by which power can be distributed. An output may comprise one or more power outlets.

Such power distribution systems have long incorporated overcurrent devices, such as conventional fuses or circuit breakers. More recently, earth leakage current (ELC) protection has been added by the addition of discrete residual current devices (RCDs). RCDs incorporating overcurrent protection have also been used. Each such device is known as a residual current breaker with overcurrent, or more frequently as an RCBO.

A typical RCBO comprises a shut-off in the form of a paddle user-manipulable to shut off power to the output circuit to which the RCBO is connected. The paddle also flicks over when the RCBO “trips” to automatically shut off power to the output circuit. The RCBO can be reset by pushing the paddle back to its operational position.

Dividing the various lights, pieces of audio equipment, pieces of video equipment and other loads between a large number of outputs minimises the disruption associated with unexpected tripping. By way of example, should one light draw excessive current, that one light (or one set of lights) powered by a single output is shut off to guard against overcurrent (and fire hazards, etc, associated therewith) whilst the show can go on with all of the other loads in operation.

It is customary to test power distribution systems and the associated loads before they are needed. In some contexts, an entire system might be built up offsite, tested, packed away, transported and reinstalled onsite, and then tested again. Despite all due diligence, unexpected tripping can and does occur from time to time. When a protection device is tripped, it can be hard to know why. By way of example, should a protection device protecting a group of lights fail, it might be necessary to individually power each light of the group in turn until the fault is found. This is of course impractical in the middle of a play.

Such investigations are sometimes fruitless. Sometimes the root cause of a breaker tripping cannot be determined. By way of example, sometimes after plugging each light back in and then repowering the entire group of lights, the trip cannot be repeated. This of course does not inspire confidence for the ongoing operation of the system.

With the foregoing in mind, the present disclosure aims to provide improvements in and for power distribution.

### SUMMARY

One aspect of the disclosure provides a power distribution system comprising a power inlet; two or more power outputs each having a respective user-actuatable shut-off; and an ELC monitoring system to provide a respective measure of ELC for each of the power outputs.

Preferably, each of the power outputs has a respective RCD, e.g. each of the power outputs may have a respective RCD comprising the respective user-actuatable shut-off. Preferably, each RCD is an RCBO.

Optionally, each power output has a respective ELC sensor. The sensor may be independent of the respective RCD. Preferably, each respective ELC sensor is a respective current transformer.

Preferably, the ELC monitoring system comprises a display to display the respective measure of ELC for each of the power outputs, e.g. the ELC monitoring system may comprise a display to display a respective measure of ELC, relative to a respective ELC trip point, for each of the power outputs.

The power distribution system may comprise a memory. Each output may have a respective individually measured trip point stored in the memory.

The power distribution system may comprise a transportable unit. The transportable unit may comprise the power inlet and the power outputs. It may also comprise the display.

The ELC monitoring system preferably comprises a respective at least one adjustable alarm threshold for each of the power outputs.

Preferably, the ELC monitoring system is configured to provide a respective ELC waveform characterization for each of the power outputs.

The power distribution system preferably comprises a datalogging system configured to log ELC. The datalogging system may be configured to log ELC associated with tripping, e.g. root-mean-square (RMS) ELC associated with tripping and/or peak ELC associated with tripping. The datalogging system may be configured to log conventional current (e.g. RMS conventional current and/or peak conventional current) associated with tripping.

The power distribution system may comprise a dimming mechanism for dimming at least one of the power outputs. The power distribution system may comprise a data-inlet for receiving electronic control signals from outside the power distribution system. The power distribution system may comprise a data-outlet such that similar power distribution systems are chainable.

Optionally, the power inlet is a 3-phase power inlet and each of the power outputs is a single-phase power output. There may be a multiple of three of the power outputs.

The power distribution system preferably comprises at least 3, e.g. at least 6, or more preferably at least 12 of the power outputs.

### BRIEF DESCRIPTION OF DRAWINGS

FIG. 1 is a perspective view of a power distribution unit;

FIG. 2 is a perspective view of a rear panel of the unit;

FIG. 3 is a front view of a portion of the unit;

FIG. 4 schematically illustrates one output protection and monitoring system; and

FIG. 5 shows one display screen.

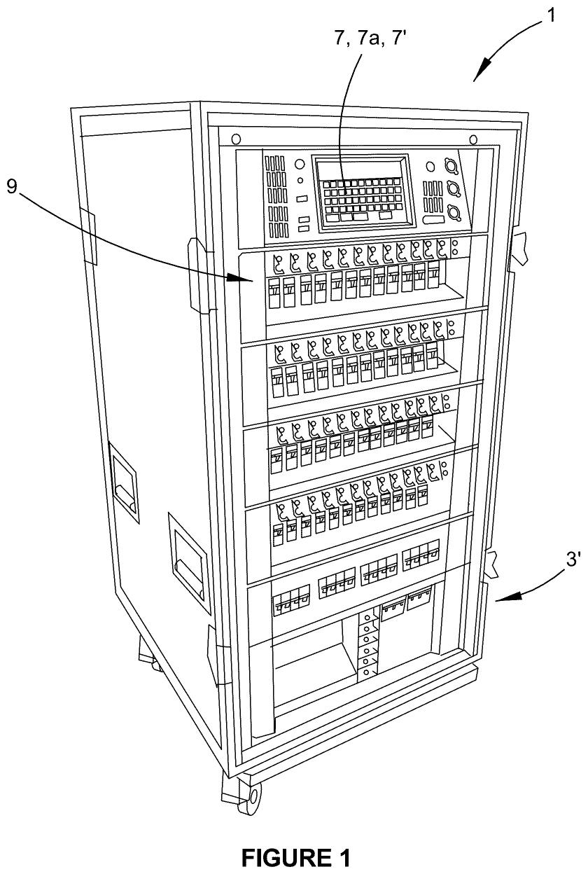

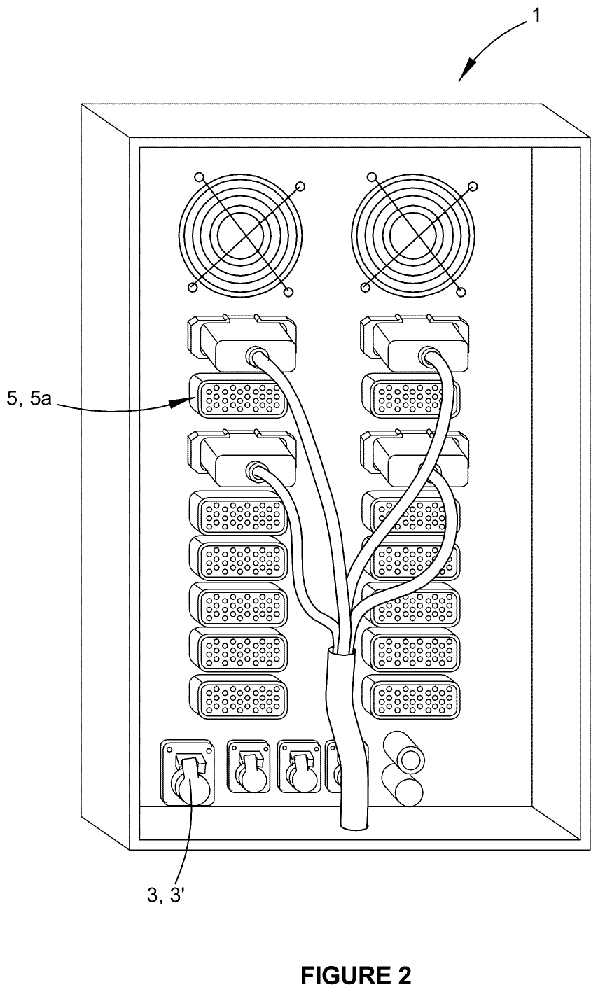

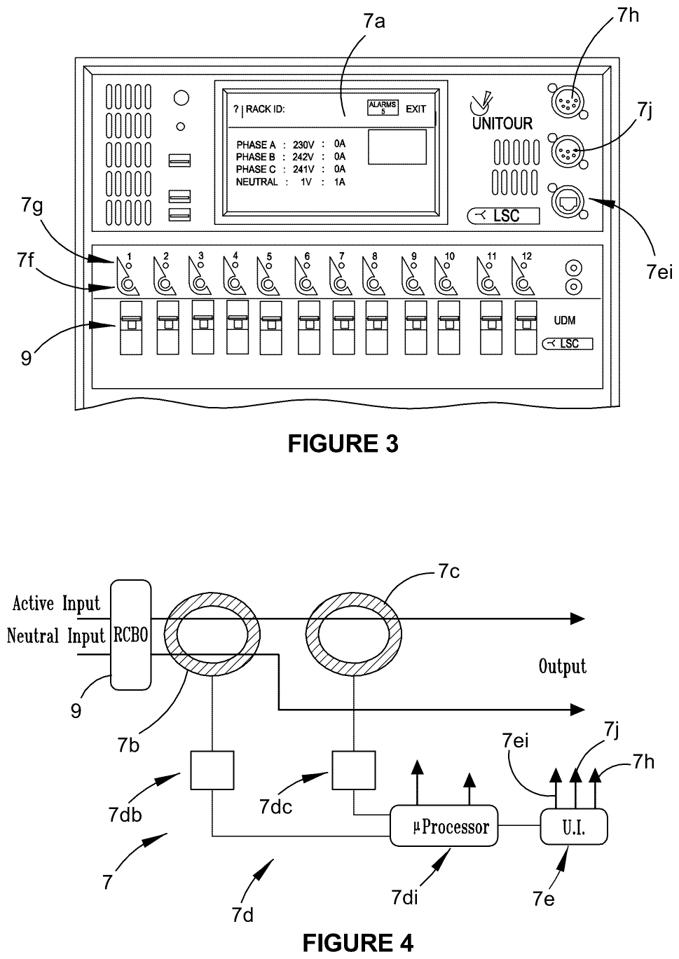

### DETAILED DESCRIPTION

Various examples are described below. The disclosure is not limited to these examples.

The power distribution system 1 comprises a transportable unit comprising a power inlet 3 in the form of a 3-phase fitting to receive power from a 3-phase power supply. This example of the system comprises 48 single-phase power outputs 5 distributed between 16 Wieland connectors 5a at the rear of the unit.

The present inventors have recognised that it would be useful for operators to better understand the ELC(s) associated with the power distribution system and be equipped to respond thereto. Indeed, the present inventors believe that many unexplained trips are in fact the result of excessive ELC.

Conventional current is at the forefront when planning how to connect loads to a power distribution system. Typical load drawing devices are reliably marked with their conventional current draw. In contrast, in the inventors' experience, ELC is not proactively considered. Indeed, the vast majority of electrical devices are not labelled with their expected ELC whereby operators have no practical way of proactively planning for and managing ELC even if they thought to do so.

ELC can vary unexpectedly. By way of example, humidity can increase earth leakage; a power distribution system might be installed and thoroughly tested and found to work perfectly and then trip as a result of increased humidity. Apparently innocuous changes in installed-system configurations can have significant effects. By way of example, a lengthy extension lead can increase ELC and sometimes power layouts etc change whereby additional extension leads (or other pieces of equipment) are required after an installation has been tested.

Further difficulty arises from variation from RCD to RCD. Many RCBOs are rated to trip at 30 mA ELC but in fact trip at lower values, e.g. in the range of 24 mA to 30 mA. Furthermore, the present inventors have recognised that many RCDs do not trip instantaneously when the ELC rises to the trip point; rather there is a delay between the trip point being reached and the RCBO tripping. During this delay, the ELC can rise above the trip point. As detailed below, some variants of the system 1 make use of this fact.

The unit comprises an ELC monitoring system 7 comprising a display 7a and a respective earth leakage sensor 7b for each of the outputs 5.

In this example, each output is equipped with a respective RCBO 9. Proprietary RCBOs (and RCDs more generally) are readily and economically available. RCDs must meet various electrical standards. Adopting proprietary RCDs helps to ensure compliance with the electrical standards.

The ELC monitoring system 7 is configured to provide a respective measure of ELC for each of the power outputs. As the wording is used herein, a “measure” is more than a mere binary indication of magnitude, e.g. more than the binary indication obtained when an RCD trips and/or a warning light illuminates in response to an ELC crossing a threshold. Preferably, the measure takes the form of a numerical value by which variations in ELC can be monitored. The numerical measure might take the form of a magnitude of the ELC, e.g. the ELC may be displayed in milliamp. Alternatively, it might take the form of a relative measure such as the ELC expressed as a percentage of a trip point of the RCBO or as a “headroom” figure corresponding to the remaining milliamps that may be leaked before reaching the trip point of the RCBO. Whilst a numerical display is preferred, there are other options. By way of example, the measure might take the form of a bar graph or any convenient form of graphic display. Indeed, audio signals are also possible.

The present inventors have recognised that a set (e.g. batch) of RCDs having the same nominal trip point (e.g. a set of RCDs of the same type) in fact have differing trip points. Accordingly, it is preferred that the trip point of each RCD be measured and stored within the system 1.

The actual trip point of the breaker might be measured as part of a calibration procedure during the initial manufacture of the system 1. Preferably the system 1 incorporates non-volatile memory for storing the calibration measurements. The calibration procedure might be repeated from time to time.

Displaying a measure of ELC relative to a measured trip point in this way enables operators to make more informed choices. By way of example, in the context of outputs each leaking 23 mA:
there is a headroom of only 1 mA on an output circuit having an RCD having a measured trip point of 24 mA, whilst
there is a headroom of 7 mA on an output circuit having an RCD with a measured trip point of 30 mA.

During a rehearsal, 7 mA may well be regarded as ample headroom to accommodate foreseeable changes in humidity etc, whereas 1 mA may well be regarded as marginal and thus prompt reconfiguration of the system prior to the performance. In this way, the risk of unexpected tripping can be reduced.

Whilst relative measures such as absolute headroom and percentage-of-trip-point are highly advantageous, a measured trip point may be advantageously employed without them. By way of example, the measured trip points might be displayed alongside real-time ELC values, taken into account when setting alarm thresholds and/or simply noted by an operator.

The RCBOs each have a shut-off in the form of a paddle that can be flicked from an operational position to a non-operational position to shut off the output. This equips users to respond to unsatisfactory variations in ELC. The shut-off enables an operator to isolate the output in response to an unsatisfactory ELC. This allows corrective action to be taken; e.g. if, during a performance, a group of lights has an ELC approaching a trip point, during the intermission the operator might toggle the paddle to isolate that output, make some adjustments such as dividing the loads between two outputs and then reset the paddle to restore power to the lights. In this way, the show can go on without interruption and with reduced risk of tripping subsequent to the intermission. The shut-off could take any convenient form. By way of example, the shut-off might take the form of a dedicated switch in addition to the RCBO.

The ELC monitoring system 7 is preferably not merely an ELC monitoring system but also monitors conventional current, and for this purpose preferably incorporates a conventional current sensor 7c. The sensors 7b, 7c preferably take the form of current transformers (CTs), although there are other options such as hall effect devices, current shunts or dedicated current-monitoring ICs. The system 7 incorporates a logic system 7d connecting the sensors 7b, 7c to the user interface 7e. The user interface 7e incorporates the screen 7a and for each output 5 a respective button 7f and a respective warning light (e.g. LED) 7g.

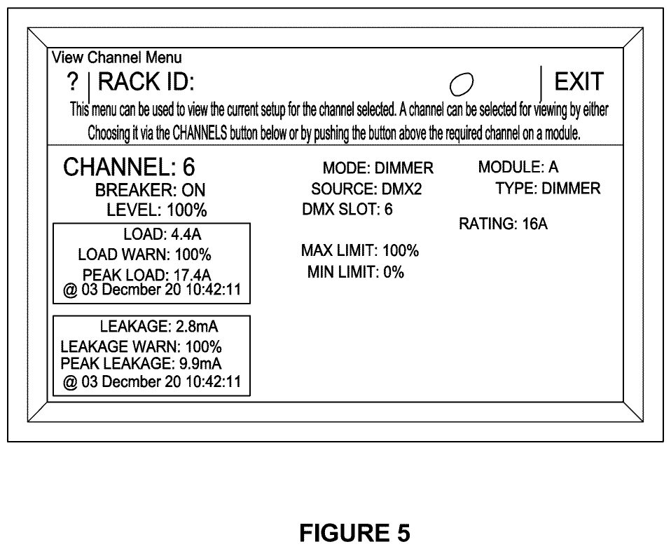

Preferably the user interface is configurable to show different pages via the screen 7a. FIG. 5 shows one potential screen displaying data in connection with the sixth output identified as ‘channel 6’. In a preferred variant of the disclosure, this page is displayed in response to pressing the button 7f for the sixth output.

This page displays the status of the breaker (‘ON’) and confirms (and provides details of) the output being in a dimmer mode (as opposed to a simple-power mode).

Details related to the last time that the breaker (i.e. RCBO in this case) tripped are displayed in boxes at the bottom left of the page. The peak conventional current and peak ELC are separately displayed. These values provide helpful diagnostic information, particularly when understood in the context of the delay between a trip point being reached and tripping in fact occurring. This display confirms that the RCBO on channel 6 is rated for 16-amp conventional current and that the last time the breaker tripped the peak conventional current was 17.4-amp whilst the peak ELC was a modest 9.9 mA. This immediately tells the operator that the breaker tripped because of excessive conventional current rather than excessive ELC.

The amount by which the peak current exceeds the trip point provides an indication of the rate at which the offending parameter is rising. In this case, the offending parameter is conventional current and rose by only 1.4-amp during the relevant delay. This modest figure suggests that the offending parameter was rising rather slowly. Similar logic is applicable if and when the ELC is the offending parameter that leads to the breaker tripping. By way of example, a peak ELC of 31 mA in the context of a 30 mA trip point is indicative of slowly rising ELC potentially associated with a problem such as rising humidity. On the other hand, a peak ELC of 30 mA beyond a 30 mA trip point is indicative of something with a much faster onset, in which case the operator might then begin investigating which piece of equipment was activated (or other event took place) at that time.

In this example, the data relating to tripping is data logged. Preferably the data log retains data for at least five trippings. Preferably both ELC and conventional current values associated with tripping are logged. Most preferably the data is time stamped. Reviewing the data log can reveal patterns that point towards the cause of the offending parameter (e.g. to the cause of excessive ELC). Logging both ELC and conventional current is particularly advantageous in the context of an RCBO. By way of example, in the context of an RCBO that nominally trips at 30 mA, a log merely indicating that the RCBO tripped at 27 mA does not make clear whether the RCBO tripped due to excessive ELC or excessive conventional current.

Preferred variants of the interface 7e comprise user-selectable display modes. Most preferably the system can display data characterising the current state of the system, e.g. a table setting out the ELC for each of a plurality (or preferably all of) the outputs may be displayable (or these ELC values might be otherwise simultaneously conveyed). Preferably the table (or other means of conveying) is configurable to convey both real-time values and peak values. Most preferably both values are RMS values. Preferably the peak value is the RMS value over one full input-voltage cycle, e.g. 0.02 seconds in the context of a 50 Hz voltage.

The peak ELC may be either: (a) the peak value on that channel since the system 1 was powered up; (b) the peak value since a logging period was manually initiated (e.g. by pressing a reset button that clears all previous peaks); (c) a peak value during a predetermined (e.g. user set) time period leading up to that moment; or (d) a combination of two or more of the above.

Whilst the voltage applied to a single phase output is typically sinusoidal and a simple resistive earth leakage would result in a correspondingly sinusoidal ELC, many earth leakages are the result of more than mere resistance. By way of example, whilst a sinusoidal ELC having an RMS value of 25 mA has an instantaneous-peak ELC of 35 mA (i.e. 25÷0.707), a non-sinusoidal ELC might have a much higher peak instantaneous ELC that trips a 27 mA breaker. In this way, displaying the peak instantaneous ELC helps the operator to better understand the state of the system, to diagnose why a breaker has tripped and to better anticipate when a breaker is likely to trip.

Displaying the peak instantaneous ELC as well as the RMS ELC provides a rudimentary characterisation of the wave form of the ELC in that an unexpected departure between these two figures is indicative of the wave form departing from sinusoidal. Such a characterisation also provides useful diagnostic information. By way of example, extraordinary departures between the peak and RMS values suggest ELCs associated with something more than a simple resistive device e.g. with something other than an extension lead. Preferred variants provide more detailed characterisations of the wave form. Most preferably the user interface 7 is configurable to graphically display a plot of the instantaneous ELC over at least one complete cycle of input voltage. From this plot, an experienced user might recognise the features characteristic of certain pieces of equipment.

Whilst the illustrated variant of the power distribution system 1 comprises a transportable unit incorporating the screen 7a, the power distribution system may comprise a data outlet to transmit ELC data to a user remote from the unit. The data outlet may be included in addition or as an alternative to the display 7a. The data outlet preferably takes the form of a wireless transmitter, potentially a wireless transmitter configured to cooperate with a telecommunications network although a wide range of connections are also possible. By way of example, in the context of a stadium concert, a set of transportable units might be spread about the stadium and connected to transmit information to a control system. Preferably the units also include data inlets to receive control signals from the control system.

Preferred variants of this system are configured to enable the user to set respective ELC warning points for each of the outputs. In some variants the warning points might be set in terms of absolute values. In other variants, the warning points might be set in terms relative to a trip point. Preferred variants of the system give users both options.

The system may be configured to alarm in response to an ELC reaching an ELC warning point. By way of example, the alarm might take the form of a visual alarm (such as a warning light), an audible alarm (such as a tone delivered by the transportable unit) or a data signal (such as an SMS message and/or email sent via a telecommunications network). Warning lights may take the form of LEDs, e.g. RGB LEDs. The power distribution system may well entail more elaborate warning logic. Preferably that logic is user adjustable. By way of example, an alarm might issue only after a period (of say a few milliseconds) of the ELC remaining continuously at or above the warning point. In this way, essentially-false alarms associated with short-lived transients can be avoided.

A preferred variant of the display screen comprises an array of boxes (or other icons) including a respective box (or other icon) for each of the outputs and in which numerical ELC values are displayed. In one preferred implementation, the system is equipped to provide a set of screens, each displaying measures for each of a plurality (or preferably all of) the outputs. Preferably these screens respectively display real-time CC, real-time ELC, peak CC and peak ELC. Most preferably an element of the user interface (e.g. a portion of the touchscreen) is actuable (e.g. touchable) to step through these screens in sequence. The element might take the form of a button or toggle switch.

Colour codes may be applied to the boxes to aid in recognition. The colour code might be applied by shading an entire box or by displaying a coloured indicia in or in the vicinity of the box. By way of example, outputs that have reached the warning point might be colour coded orange whereas outputs that have tripped might be colour coded red. Multiple warning points are possible. By way of example, a lower ELC warning point might be set to cause one box to be colour coded yellow before it moves into the orange phase. In this way, an operator can, at a glance, assess the overall status of the system and identify where their efforts are best directed to address outputs that have already tripped and to take pre-emptive action as required. Of course, other forms of graphical user interface, and indeed other forms of interface more generally, are possible. By way of example, a portion of the screen and/or an associated warning light might flash in addition or instead of an output being colour coded red. Preferably more prominent alarms are assignable to outputs deemed to be more important.

The screen of the interface 7e is preferably a touchscreen, e.g. an 18 cm TFT colour graphical touchscreen. Preferably the box (or other icon) can be touched to bring up a screen dedicated to that particular output e.g. to bring up the screen of FIG. 5. Alternatively or additionally, a similar operating procedure may be implemented utilising a pointing device (such as a mouse) or other interface-element such as a button. Other forms of display such as graphical monochrome or LED/LCD alphanumeric could be used. In one preferred implementation, the lights 7g are driven to change colour/state to indicate: (a) passing a warning point; (b) CC passing a warning point; (c) breaker tripped due to CC overload; and (d) breaker tripped due to ELC overload.

The Wieland connectors 5a are but one example. The outputs may comprise 19 pin Socapex connectors, 10 pole Wieland connectors, 16 pole Wieland connectors, CEEform connectors or Neutrik powerCON connectors amongst other options. Indeed, the outputs may comprise GPOs. In this example, the power outputs are spread across a set of subunits suitable to rack mountings. In this case there are four subunits.

In this case each subunit carries 12 channels. Preferably the system 1, and most preferably each subunit, comprises a multiple of 3 outputs whereby an incoming three phase power supply can be divided equally between the outputs. There are other options, e.g. some variants of the system 1 may comprise a single phase power inlet.

In this example, the three phase power inlet 3 forms part of a 400 Amp three phase power supply 3′ at the base of the unit 1.

In this example, the interface 7e is part of a control module (UHM) 7′ at the top of the unit 1 and each sub unit has its own processor 7di. The logic system 7d and user interface 7e are preferably built into the transportable unit. In this example, each of the sensors 7b, 7c is connected to a processor 7di via respective analog filters 7db, 7dc. The processors apply logic to the filtered sensor output and communicate with the control module via a communication system. The control module incorporates a logic system (e.g. comprising one or more processors) to receive information from the processors 7di and drive the user interface 7e. The connection might be wired or wireless. The logic system of the interface 7e connects to data ports 7h, 7j via an RS485 connection and also has an ethernet connection 7ei. Modbus, RS232, RS485, RDM, ZigBee and BlueTooth are convenient connection options.

In this example the processor 7di is a microprocessor comprising an analog input A-D to receive the signals from the filters 7db, 7dc. Alternatively the signals might be fed to an external dedicated A-D converter. Output from the converter might be connected to a digital input of the microprocessor. The inputs could be multiplexed to reduce the number of microprocessor pins required.

Other forms of communication such as RS-232, LoRa, WiMax or Bluetooth could be used. Distributed logic systems are also possible. By way of example, the filters 7db, 7dc might be replaced by simple transmitters that transmit (e.g. via the internet) signals directly relatable to the output of the sensors 7b, 7c. The processor 7di and user interface 7e might be replaced by a computer such as a desktop computer, laptop computer or tablet configured to receive and process such signals.

Various examples of the technology described herein may be usefully employed in contexts such as audio, video and lighting systems in theatres and in contexts such as tv stations, concerts, houses of worship, museums, conferences, trade shows, film and corporate events etc. For this purpose, preferred variants of the system 1, or at least the unit comprising the input and the outputs, are transportable. Preferred variants are of a scale capable of being manually handled by one or two operators. This variant of the transported unit includes castors. A preferred method of providing power to a site entails transporting a transportable unit to the site and then connecting of the unit to the loads. Preferably the transport comprises road transport.

Preferably the system 1 is capable of dimming some, or potentially all, of the outputs. The dimming may entail triac-control. Preferably each of the dimmable outputs is separately controllable. Most preferably, the unit 1 is configured to receive an electronic control signal by which the dimming function can be controlled. For this purpose, the controlling unit 7′ incorporates a data inlet 7h in the form of an XLR connector to receive a DMX512 signal by which up to 512 channels can be controlled. Preferred variants of the system also incorporate a data outlet 7j via which plural systems 1 can be chained together. By way of example, a cable running from the data outlet 7j may connect the system 1 to a downstream similar system. In this example, the data inlet 7h and the data outlet 7j are directly connected to each other and connected to the logic system of the interface 7e by an RS485 connection.

The XLR connector and DMX512 signal protocol are a convenient mechanism by which the system 1 is controllable. sACN and ArtNet are other convenient mechanisms. In this example, the system 1 incorporates all three mechanisms. It may also incorporate other control protocols. The sACN and ArtNet mechanisms make use of signals carried on ethernet and/or arrive at the unit via connector 7ei. The connector 7ei can also be used for outgoing communication, e.g. for SMS, emails and remote monitoring via products such as LSC Control Systems' Houston X monitoring program.

Whilst various examples are described herein, other examples may well be useful. By way of example, whilst the power distribution 7 monitors the ELC of each output, a variant of the system 1 that monitors the global ELC of the system 1 and the associated loads would be useful; instead of each output having its own current transformer, a current transformer (or other sensor) may be associated with the power inlet. A global ELC sensor may also be useful in combination with individual output ELC sensors.

The term “comprises” and its grammatical variants has a meaning that is determined by the context in which it appears. Accordingly, the term should not be interpreted exhaustively unless the context dictates so.

1. A power distribution system comprising:
a power inlet;
two or more power outputs each having a respective user-actuatable shut-off and a respective residual current device (RCD); and
an earth leakage current (ELC) monitoring system configured to provide a respective measure of ELC for each of the power outputs;
wherein each power output comprises a respective ELC sensor independent of the respective RCD; and
a memory configured to store a respective measured trip point for each respective RCD.

2. The power distribution system of claim 1 wherein each respective RCD comprises the respective user-actuatable shut-off.

3. The power distribution system of claim 1 wherein each respective RCD is a respective residual current breaker with overcurrent (RCBO).

4. The power distribution system of claim 1 wherein each respective ELC sensor is a respective current transformer.

5. The power distribution system of claim 1 wherein the ELC monitoring system comprises a display configured to display the respective measure of ELC for each of the power outputs.

6. The power distribution system of claim 1 wherein the ELC monitoring system comprises a display configured to display a respective measure of ELC, relative to the respective measured trip point, for each of the power outputs.

7. The power distribution system of claim 5 comprising a transportable unit, the transportable unit comprising the power inlet, the power outputs and the display.

8. The power distribution system of claim 1 comprising a transportable unit, wherein the transportable unit comprises the power inlet and the power outputs.

9. The power distribution system of claim 1 wherein the ELC monitoring system comprises a respective at least one adjustable alarm threshold for each of the power outputs.

10. The power distribution system of claim 1 wherein the ELC monitoring system is configured to provide a respective ELC waveform characterization for each of the power outputs.

11. The power distribution system of claim 1, comprising a datalogging system coupled to the ELC monitoring system for each of the power outputs and configured to log the respective measure of ELC for the respective power output.

12. The power distribution system of claim 11 wherein:
each RCD is configured to trip when a current rises above a preset trip point; and
the datalogging system is configured to log the respective measure of ELC associated with an RCD tripping.

13. The power distribution system of claim 12 wherein the datalogging system is configured to log root-mean-square (RMS) ELC associated with the RCD tripping.

14. The power distribution system of claim 12 wherein the datalogging system is configured to log peak ELC associated with the RCD tripping.

15. The power distribution system of claim 12 wherein the datalogging system is configured to log conventional current associated with tripping.

16. The power distribution system of claim 1 comprising a dimming mechanism configured to dim at least one of the power outputs.

17. The power distribution system of claim 1 comprising a data inlet configured to receive electronic control signals from outside the power distribution system.

18. The power distribution system of claim 17 comprising a data outlet configured to be coupled to the data inlet of a second power distribution system.

19. The power distribution system of claim 1 wherein the power inlet is a 3-phase power inlet and each of the power outputs is a single-phase power output.

20. The power distribution system of claim 1 wherein the two or more power outputs comprise a multiple of three power outputs.

21. (canceled)
